(19) United States
(12) Patent Application Publication
(10) Pub. No.: US 2026/0040797 A1
(43) Pub. Date: Feb. 5, 2026

(54) DISPLAY PANEL, METHOD FOR MANUFACTURING THE SAME, AND DISPLAY DEVICE

(71) Applicant: HKC CORPORATION LIMITED, Shenzhen (CN)

(72) Inventors: JING CAO, Shenzhen (CN); Linlin QIU, Shenzhen (CN); Lei JIANG, Shenzhen (CN); Guangsheng LI, Shenzhen (CN); Lidan YE, Shenzhen (CN)

(21) Appl. No.: 19/281,793

(22) Filed: Jul. 28, 2025

(30) Foreign Application Priority Data
Jul. 31, 2024 (CN) 202411045903.1

(51) Int. Cl. H10K 59/80; H10K 59/12; H10K 59/122

(52) U.S. Cl. CPC H10K 59/873; H10K 59/1201; H10K 59/122

(57) ABSTRACT

A display panel, a method for manufacturing the same, and a display device are disclosed. The display panel includes a substrate, multiple overhang structures, multiple light-emitting elements, a first inorganic encapsulation layer, and an organic encapsulation layer. The first inorganic encapsulation layer is arranged on the side of the overhang structures facing away from the substrate. The organic encapsulation layer is arranged on the side of the first inorganic encapsulation layer facing away from the overhang structure. Each overhang structure includes a pixel defining layer, a conductive layer, and an eaves blocking layer that are stacked in sequence. The eaves blocking layer includes at least one groove structure in the side facing away from the conductive layer. The at least one groove structure is sequentially filled with a light-emitting material and a first inorganic encapsulating material.

### CROSS-REFERENCE TO RELATED APPLICATIONS

The present application claims the priority and benefit of Chinese patent application number 2024110459031, titled “Display Panel, Method for Manufacturing the Same, and Display Device” and filed Jul. 31, 2024 with China National Intellectual Property Administration, the entire contents of which are incorporated herein by reference.

### TECHNICAL FIELD

The present application relates to the field of display technology, and more particularly relates to a display panel, a method for manufacturing the same, and a display device.

### BACKGROUND

The description provided in this section is intended for the mere purpose of providing background information related to the present application but doesn not necessarily constitute prior art.

Organic light-emitting diodes (OLEDs) have become increasingly mature in mass production technology due to their advantages, such as surface light source, cold light, energy efficiency, fast response, flexibility, ultra-thinness, and low cost. Due to the poor stability of OLEDs, which are highly sensitive to water, oxygen, and heat, the encapsulation technology thereof is particularly critical.

In order to achieve high resolution and colorization of passive matrix OLEDs and better address issues such as low resolution of the cathode template and low device yield, the actual research has introduced a cathode isolation pillar structure. This means that no metal template is used in device fabrication; instead, isolation pillars are fabricated on the substrate before the deposition of organic films and metal cathodes, and ultimately achieves the separation of different pixels in the device and forming a pixel matrix. The shape of the isolation pillar is key to the isolation effect. The base insulating buffer layer is used to solve the anode short circuit problem between pixels. Meanwhile, inverted trapezoidal isolation pillars are used to solve the organic light-emitting layer short circuit problem between adjacent pixels. This inverted trapezoid is also called an overhang structure. To protect the organic light-emitting layer, a first inorganic encapsulation layer is applied above the organic light-emitting layer for encapsulation, followed by the inkjet printing of the organic encapsulation layer over the entire surface. The formation of peeling or cracks between the encapsulated layers may accelerate the aging of the OLED organic light-emitting layer device. Therefore, strict encapsulation is necessary to extend the lifespan and improve stability.

However, the encapsulation adhesion between the first inorganic encapsulation layer and the organic encapsulation layer is currently relatively weak, making it prone to delamination risks between the layers, leading to potential risks of water and oxygen intrusion.

### SUMMARY

One objective of this application is therefore to provide a display panel, a method for manufacturing the same, and a display device that improve the adhesion between the encapsulated layers and ensure the encapsulating effect.

This application discloses a display panel, which includes a substrate, a plurality of overhang structures, a plurality of light-emitting elements, and a first inorganic encapsulation layer. The plurality of overhang structures are disposed on the substrate and are spaced apart from each other. The adjacent overhang structures are arranged in an encircling manner to form pixel openings. The plurality of light-emitting elements are respectively disposed inside the pixel openings. The first inorganic encapsulation layer is disposed on a side of the overhang structure facing away from the substrate. The organic encapsulation layer is disposed on a side of the first inorganic encapsulation layer facing away from the overhang structure. Each overhang structure includes a pixel defining layer, a conductive layer, and an eaves blocking layer that are sequentially stacked. At least one groove structure is formed in the side of the eaves blocking layer facing away from the conductive layer. The groove structure is sequentially filled with a light-emitting material and a first inorganic encapsulating material.

In some embodiments, along the orientation in which the overhang structure is arranged, the width of a groove bottom of the groove structure is greater than the width of a groove opening of the groove structure.

In some embodiments, a cross section of the groove structure is a trapezoidal structure, and a base angle of the trapezoidal structure is 60°˜80°.

In some embodiments, assuming the groove structure has a groove depth denoted as h, a groove opening width denoted as b, and a thickness of the eaves blocking layer denoted as H, then H is 3 μm and ⅓H≤h≤½H, and 1 μm≤h≤1.5 μm; b is set to the range of 1 μm≤b≤1.5 μm.

In some embodiments, the overhang structure is arranged along a column orientation or a row orientation, and the groove structure runs through the entire eaves blocking layer along the orientation of the column or row.

In some embodiments, the overhang structures include a first overhang structure and a second overhang structure. The first overhang structure is correspondingly arranged between adjacent light-emitting elements. The second overhang structure is arranged on a side facing away from the respective light-emitting element. The number of groove structures on the first overhang structure is greater than the number of groove structures on the second overhang structure.

In some embodiments, the overhang structures include a first overhang structure and a second overhang structure. The display panel includes a first spacing region formed between adjacent light-emitting elements of the same color and a second spacing region formed between adjacent light-emitting elements of different colors. The first overhang structure is correspondingly arranged in the first spacing region. The second overhang structure is correspondingly arranged in the second spacing region. A cross-sectional area of the groove structure on the first overhang structure is smaller than that on the second overhang structure. The number of groove structures on the first overhang structure is smaller than that on the second overhang structure.

In some embodiments, a plurality of first groove structures are formed on the eaves blocking layer of each overhang structure along a scan line orientation. A plurality of second groove structures are formed on the eaves blocking layer of each overhang structure along a data line orientation. A cross-sectional area of the first groove structure is smaller than that of the second groove structure.

The present application further discloses a method for manufacturing a display panel, which is applicable to the above-mentioned display panel and includes the following operations:
providing a back plate including a driving circuit, an anode layer, and a pixel defining layer;
forming a conductive layer on the pixel defining layer of the back plate;
forming an eaves blocking layer on the conductive layer, where the pixel defining layer, the conductive layer, and the eaves blocking layer are stacked to form an overhang structure;
forming a groove structure in the eaves blocking layer;
coating a photoresist material over the entire surface to form a photoresist layer;
forming pixel openings between adjacent overhang structures;
depositing a light-emitting material above the anode layer to form a light-emitting layer, with a part of the light-emitting material falling into the groove structure;
depositing a cathode material above the light-emitting layer to form a cathode layer, where the cathode layer is connected via the conductive layer, and where the anode layer, the light-emitting layer, and the cathode layer are stacked to form a light-emitting element;
coating a first encapsulating material above the overhang structure and the cathode layer to form a first inorganic encapsulation layer, where a part of the first encapsulating material falls into the groove structure and covers the light-emitting material;
removing the photoresist layer;
repeating the above operations of forming the light-emitting element and the first inorganic encapsulation layer to achieve the formation of all light-emitting elements and the encapsulation with the first inorganic encapsulation layer; and
performing a full-surface encapsulation above the first inorganic encapsulation layer to obtain an encapsulated display panel.

The present application further discloses a display device including the above-described display panel.

Compared with the related art, where the encapsulation adhesion between the first inorganic encapsulation layer and the organic encapsulation layer is relatively weak, leading to the risk of delamination between the layers, the display panel in this application includes a substrate, a plurality of overhang structures, a plurality of light-emitting elements, and a first inorganic encapsulation layer. The plurality of overhang structures are disposed on the substrate and are spaced apart from each other, and a pixel opening is formed between adjacent overhang structures. The plurality of light-emitting elements are arranged in the pixel openings in one-to-one correspondence. The first inorganic encapsulation layer is disposed on the side of the overhang structure facing away from the substrate, and the organic encapsulation layer is disposed on the side of the first inorganic encapsulation layer facing away from the overhang structure. The overhang structure includes a pixel defining layer, a conductive layer, and an eaves blocking layer that are stacked in sequence. On the side of the eaves blocking layer facing away from the conductive layer, at least one groove structure is disposed, and the groove structure is filled with a light-emitting material and a first inorganic encapsulating material in sequence. The light-emitting material and the first inorganic encapsulating material are deposited during the subsequent evaporation deposition of the light-emitting element and the encapsulation of the first inorganic encapsulation layer, so that the first inorganic encapsulation layer forms a discontinuous encapsulation on the overhang structure. This interrupts the continuity of the first inorganic encapsulation layer, thereby cutting off the path for moisture and oxygen intrusion between adjacent pixels. Furthermore, the organic encapsulation layer above the first inorganic encapsulation layer forms a relatively strong adhesion at the groove structure.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative efforts. In the drawings:

FIG. 1 is a schematic diagram of a display device provided in this application.

FIG. 2 is a cross-sectional schematic diagram of the display panel provided in this application.

FIG. 3 is a partial enlarged schematic diagram of portion A shown in FIG. 2.

FIG. 4 is a schematic diagram of an overhang structure provided in a first embodiment of this application.

FIG. 5 is a partial enlarged schematic diagram of portion B shown in FIG. 4.

FIG. 6 is a schematic diagram of a display panel in a top view provided by a third embodiment of the present application

FIG. 7 is a flowchart of a method for manufacturing a display panel provided by the present application.

In the drawings: 10, display device; 100, display panel; 110, substrate; 120, overhang structure; 121, pixel defining layer; 122, conductive layer; 123, eaves blocking layer; 124, first overhang structure; 125, second overhang structure; 126, first pixel defining layer; 127, first conductive layer; 128, first eaves blocking layer; 129, second pixel defining layer; 130, second conductive layer; 131, second eaves blocking layer; 140, first inorganic encapsulation layer; 150, groove structure; 151, first groove structure; 152, second groove structure; 160, light-emitting element; 161, first color light-emitting element; 162, second color light-emitting element; 163, first spacing region; 164, second spacing region; 165, light-emitting layer; 166, light-emitting material; 167, first inorganic encapsulating material; 170, anode layer; 180, cathode layer; 190, organic encapsulation layer; 200, second inorganic encapsulation layer.

### DETAILED DESCRIPTION OF EMBODIMENTS

It should be understood that the terms used herein, the specific structures arrangements, and the functional details disclosed herein are merely representative for describing some specific embodiments, but the present application may be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “second orientation”, and “first orientation”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

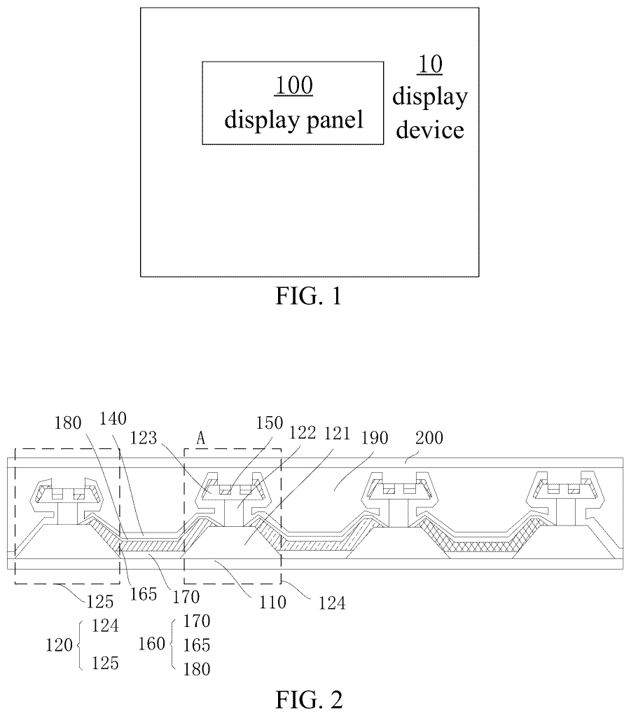

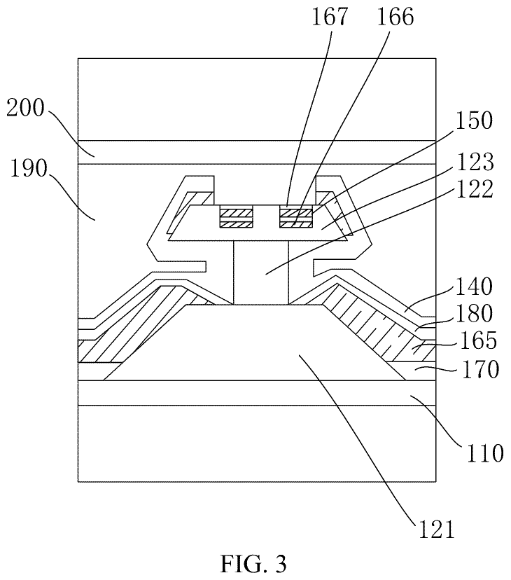

FIG. 1 is a schematic block diagram of a display device 10 provided in this application. FIG. 2 is a cross-sectional schematic diagram of a display panel 100 provided in this application. FIG. 3 is a partial enlarged schematic diagram of portion A shown in FIG. 2. As shown in FIGS. 1-3, the present application discloses a display device 10, which includes a display panel 100. The display panel 100 includes a substrate 110, a plurality of overhang structures 120, a plurality of light-emitting elements 160, a first inorganic encapsulation layer 140, and an organic encapsulation layer 190. The plurality of overhang structures 120 are spaced apart and disposed on the substrate 110. Adjacent overhang structures are arranged in an encircling manner to form pixel openings. The plurality of light-emitting elements 160 are arranged in the plurality of pixel openings in one-to-one correspondence. The first inorganic encapsulation layer 140 is disposed on the side of the overhang structure 120 facing away from the substrate 110. The organic encapsulation layer 190 is disposed on the side of the first inorganic encapsulation layer 140 facing away from the overhang structure 120. The overhang structure 120 includes a pixel defining layer 121, a conductive layer 122, and an eaves blocking layer 123 that are stacked in sequence. On the side of the eaves blocking layer 123 facing away from the conductive layer 122, at least one groove structure 150 is disposed. The groove structure 150 is filled with a light-emitting material 166 and a first inorganic encapsulating material 167 in sequence.

Compared with the related art, where the encapsulation adhesion between the first inorganic encapsulation layer 140 and the organic encapsulation layer 190 is relatively weak, leading to the risk of delamination between the layers, the display panel 100 in this application includes a substrate 110, a plurality of overhang structures 120, a plurality of light-emitting elements 160, and a first inorganic encapsulation layer 140. The plurality of overhang structures 120 are spaced apart on the substrate 110, and adjacent overhang structures 120 are in an encircling manner to form pixel openings. The plurality of light-emitting elements 160 are arranged in the pixel openings in one-to-one correspondence. The first inorganic encapsulation layer 140 is disposed on the side of the overhang structure 120 facing away from the substrate 110, and the organic encapsulation layer 190 is disposed on the side of the first inorganic encapsulation layer 140 facing away from the overhang structure 120. The overhang structure 120 includes a pixel defining layer 121, a conductive layer 122, and an eaves blocking layer 123 that are stacked in sequence. On the side of the eaves blocking layer 123 facing away from the conductive layer 122, at least one groove structure 150 is disposed, and the groove structure 150 is filled with a light-emitting material 166 and a first inorganic encapsulating material 167 in sequence. The light-emitting material 166 and the first inorganic encapsulating material 167 are deposited during the subsequent evaporation deposition of the light-emitting element 160 and the encapsulation of the first inorganic encapsulation layer 140, so that the first inorganic encapsulation layer 140 forms a discontinuous encapsulation on the overhang structure 120. This interrupts the continuity of the first inorganic encapsulation layer 140, thereby cutting off the path for moisture and oxygen intrusion between adjacent pixels. Furthermore, the organic encapsulation layer 190 above the first inorganic encapsulation layer 140 forms a relatively strong adhesion at the groove structure 150.

The present application will be described in detail below with reference to the accompanying drawings and some optional embodiments.

### First Embodiment

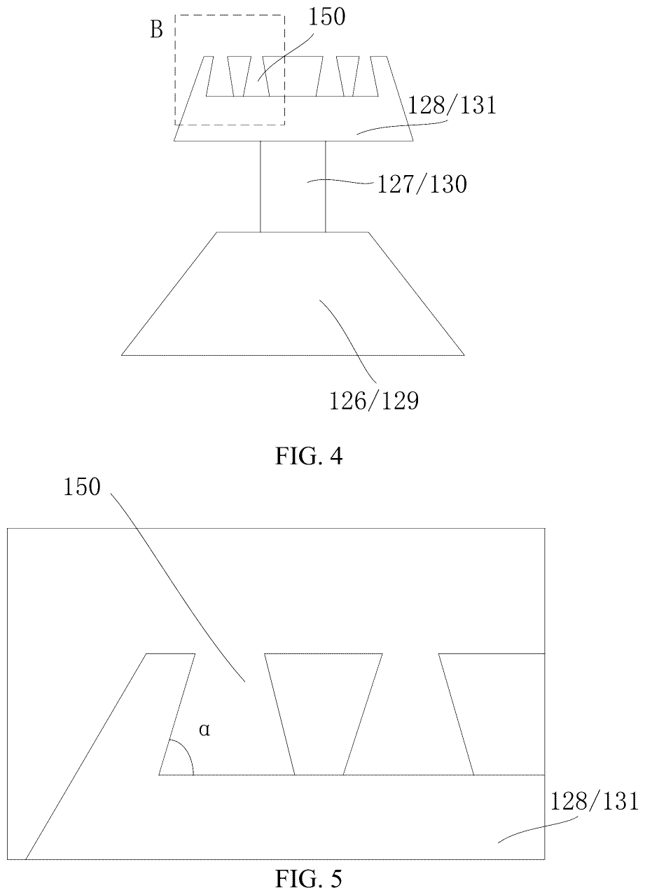

As shown in FIG. 2, the light-emitting element is a sandwich structure formed by sequentially stacking an anode layer 170, a light-emitting layer 165, and a cathode layer 180. FIG. 4 is a schematic diagram of an overhang structure 120 (as shown in FIG. 2) provided in a first embodiment of the present application. FIG. 5 is a partially enlarged schematic diagram of portion B shown in FIG. 4. As shown in FIG. 4 to FIG. 5, along the orientation in which the overhang structure 120 is arranged, the width of a groove bottom of the groove structure 150 is greater than the width of a groove opening of the groove structure 150. That is, the groove structure 150 may be a trapezoidal structure. The groove structure 150 adopts an undercut pattern design, so that when the organic light-emitting material 166 (as shown in FIG. 3) is subsequently evaporation-deposited, the residual organic material evaporation-deposited on the side wall of the groove structure 150 can be effectively reduced. Furthermore, by depositing the organic light-emitting material 166 and the first inorganic encapsulating material 167 into the groove structure 150, the accumulation of the light-emitting material 166 and the first inorganic encapsulating material 167 above the eaves blocking layer 123 can be avoided, thus reducing the “climbing” phenomenon at this position during the subsequent encapsulation with the organic encapsulation layer 190 (as shown in FIGS. 2 and 3). A second inorganic encapsulation layer 200 may further be encapsulated on the side of the organic encapsulation layer 190 facing away from the first inorganic encapsulation layer 140, so as to further improve the tightness of the encapsulation.

The light-emitting elements 160 of the display panel 100 may include three colors, namely a red light-emitting element, a green light-emitting element, and a blue light-emitting element. Therefore, when depositing the light-emitting layers 165 by evaporation, each color of the light-emitting layer 165 must undergo a separate full-surface evaporation deposition, followed by deposition of the first inorganic encapsulation layer 140, and then patterning to form the light-emitting layers 165 within the corresponding pixel openings. Thus, three sequential evaporation-deposition processes of the light-emitting layers 165 of different colors and the encapsulation using the first inorganic encapsulation layer are required to complete the fabrication of the organic light-emitting elements 160 of three different colors.

In this way, when fabricating the light-emitting elements 160 of three colors, a light-emitting material of a first color, a first layer of the first inorganic encapsulating material, a light-emitting material of a second color, a second layer of the first inorganic encapsulating material, a light-emitting material of a third color, a third layer of the first inorganic encapsulating material, a plurality of layers of the light-emitting material 166, and a plurality of layers of the first inorganic encapsulating material 167 may be sequentially formed in the groove structure 150 to form the encapsulation barrier structure. If water vapor invades from the outside through the organic encapsulation layer, the light-emitting material 166 of the encapsulation barrier structure is an organic material and so can also absorb water vapor, while the inorganic encapsulating material is capable of blocking water vapor. They are sandwiched together to further improve the effect of blocking water vapor.

The groove structure 150 may be filled with two colors of light-emitting materials and two layers of the first inorganic encapsulating material, or the groove structure 150 may be filled with only one layer of the light-emitting material 166 and one layer of the first inorganic encapsulating material 167, which is not limited herein.

Further referring to FIG. 5, assuming that the base angle of the trapezoidal structure is α, then the value of α may be 60° to 80° so that the feasibility of the etching process can be better ensured. Further referring to FIGS. 2 and 3, assuming the groove depth of the groove structure 150 is h, the width of the groove opening is b, and the thickness of the eaves blocking layer 123 is H, then H=3 μm and ⅓H≤h≤½H, so 1 μm≤h≤1.5 μm, and b is set to the range of: 1 μm≤b≤1.5 μm. Since the thickness of the first inorganic encapsulation layer 140 may be less than that of the eaves blocking layer 123, in order to interrupt the continuity of the encapsulation by the first inorganic encapsulation layer 140, the depth of the groove structure 150 needs to be greater than the thickness of the first inorganic encapsulation layer 140. This ensures that during the encapsulation of the first inorganic encapsulation layer 140, the first inorganic encapsulating material 167 at the position corresponding to the groove structure 150 can fully fall into the groove structure 150. In order to ensure the strength of the eaves blocking layer 123, the maximum depth of the groove structure 150 is limited to ½ of the thickness of the eaves blocking layer 123. Of course, the groove structure 150 may also adopt a rectangular or other shape design, as long as it can ensure the interruption of the continuity of the encapsulation of the first inorganic encapsulation layer 140. No limitation therefore is made in this regard.

The number of groove structures 150 on each overhang structure 120 may be set to be the same. Referring to FIG. 4, when there are two groups of groove structures 150 on the eaves blocking layer 123, namely a total of four groove structures 150 are formed, then the width of the groove opening of the groove structure 150 may be 1.5 μm. In each group of groove structures 150, the spacing between adjacent groove structures 150 needs to be slightly greater than the width of the groove opening. Due to the undercut design of the trapezoidal structure, which is slightly wider at the bottom, a margin needs to be reserved to ensure that the two groove structures 150 are not etched through. Therefore, the spacing between the first groove structure 151 and the second groove structure 152 is greater than 1.5 μm. When there are three groups of groove structures 150, since the width of the eaves blocking layer 123 is fixed, the groove opening width of each groove structure 150 and the spacing between two groups of groove structures 150 can be appropriately reduced. Furthermore, the number of groove structures 150 can be designed and adjusted depending on the actual size of the display panel 100.

The overhang structures 120 are arranged in columns or rows. In the column or row orientation, the groove structures 150 penetrate through the entire eaves blocking layer 123. That is, each groove structure 150 forms an upward-facing opening in the eaves blocking layer 123 and penetrates both ends of the eaves blocking layer 123. It can therefore be formed with a single etching process, which simplifies the manufacturing process. Of course, it is also possible for the groove structure 150 not to penetrate through the eaves blocking layer 123. The specific design can be determined according to actual conditions, and no limitation is made herein.

### Second Embodiment

Referring to FIG. 2, as a second embodiment of the present application, the difference between this embodiment and the first embodiment is that the overhang structure 120 includes a first overhang structure 124 and a second overhang structure 125. The first overhang structure 124 is correspondingly disposed between adjacent light-emitting elements 160. The second overhang structure 125 is disposed on a side facing away from the respective light-emitting element 160. The first overhang structure 124 and the second overhang structure 125 have the same size. The first overhang structure 124 includes, in order, a first pixel defining layer 126, a first conductive layer 127, and a first eaves blocking layer 128 that are stacked successively. The second overhang structure 125 includes, in order, a second pixel defining layer 129, a second conductive layer 130, and a second eaves blocking layer 131 that are stacked successively. A plurality of groove structures 150 are disposed on each of the first eaves blocking layer 128 and the second eaves blocking layer 131. The number of groove structures 150 on the first eaves blocking layer 128 is less than that on the second eaves blocking layer 131.

That is, the groove structures 150 at the edges of the pixel area are arranged relatively densely, while those within the pixel area are arranged more sparsely. Since gaps may exist near the edges of the display panel 100 due to the stacking of various film layers, there is a higher possibility of moisture invasion, while the pixel area in the center of the display panel 100 has a lower risk of moisture ingress. Therefore, with this design, the manufacturing process for the pixel area in the center can be relatively simplified, avoiding damage to other film layers in the pixel area which may otherwise increase the likelihood of moisture ingress.

### Third Embodiment

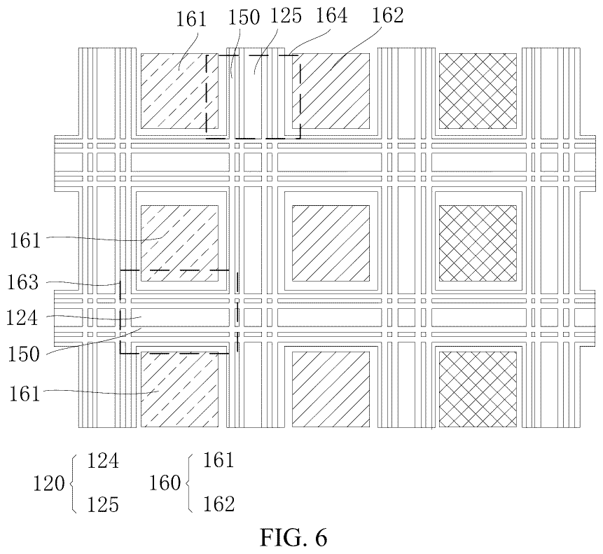

FIG. 6 is a schematic top view of a display panel 100 according to a third embodiment of the present application. As shown in FIG. 6, as the third embodiment of the present application, the difference from the first and second embodiments is that the overhang structures 120 includes a first overhang structure 124 and a second overhang structure 125. The light-emitting elements 160 include at least a plurality of first color light-emitting elements 161 and a plurality of second color light-emitting elements 162. A first spacing region 163 is formed between two adjacent first color light-emitting elements 161. A second spacing region 164 is formed between the first color light-emitting element 161 and second color light-emitting element 162 that are adjacent to each other. The first overhang structure 124 is correspondingly disposed in the first spacing region 163. The second overhang structure 125 is correspondingly disposed in the second spacing region 164.

The size of the first overhang structure 124 is smaller than that of the second overhang structure 125. The number of groove structures 150 on the first eaves blocking layer 128 is less than the number of groove structures 150 on the second eaves blocking layer 131.

That is, light-emitting elements 160 of the same color can use light-emitting layers made from the same material, while light-emitting elements 160 of different colors need to use light-emitting layers made from different materials. Therefore, the size of the overhang structure 120 between light-emitting elements 160 of the same color may be made relatively narrower, while the overhang structure 120 between light-emitting elements 160 of different colors may be made relatively wider to improve the isolation effect. In addition, the overhang structure 120 between light-emitting elements 160 of different colors not only needs to separate adjacent pixels but also needs to electrically connect the cathodes of adjacent light-emitting elements 160. Therefore, the size of the overhang structure 120 between light-emitting elements 160 of different colors may be made relatively wider. As a result, more groove structures 150 may be disposed in the relatively wider overhang structures 120, while fewer groove structures 150 may be disposed in the relatively narrower overhang structures 120, thus ensuring the disconnection of the encapsulation continuity of the first inorganic encapsulation layer 140 while making the overall process easier to implement and reducing the complexity of processing operations. Furthermore, the encapsulation adhesion between the first inorganic encapsulation layer 140 and the organic encapsulation layer 190 can be better guaranteed. The overhang structure 120 between light-emitting elements 160 of the same color may not serve the purpose of electrically connecting the cathodes. That is, the four sides of the cathode of the light-emitting element 160 may overlap the overhang structure 120. After differentiating the widths of the overhang structures 120, the cathode on some sides of the light-emitting element 160 may not overlap and connect with the overhang structure 120, while the cathode on the other sides may still overlap and connect with the overhang structure 120. This still forms a cathode conductive network, ensuring that all cathodes are electrically connected.

### Fourth Embodiment

As a fourth embodiment of the present application, this embodiment differs from the first, second, and third embodiments in that, along the scan line orientation, the eaves blocking layer 123 of each overhang structure 120 includes a plurality of first groove structures 151. Along the data line orientation, the eaves blocking layer 123 of each overhang structure 120 includes a plurality of second groove structures 152 in. A cross-sectional area of the first groove structure 151 is smaller than a cross-sectional area of the second groove structure 152.

That is, in the intersecting orientation, a plurality of groove structures 150 of different sizes are formed, creating discontinuous interfaces of the first inorganic encapsulation layer 140 at the positions of the groove structures 150. During the encapsulation of the organic encapsulation layer 190, different-sized encapsulation contact interfaces are formed between the two encapsulation layers, improving encapsulation adhesion while making the entire encapsulation structure more uniform. Of course, the cross-sectional area of the groove structure 150 in the scan line orientation may be made larger than the cross-sectional area of the groove structure 150 in the data line orientation. Alternatively, a plurality of groove structures 150 of different sizes may be formed in the scan line orientation, and a plurality of groove structures 150 of different sizes may also be formed in the data line orientation. The design may be adjusted depending on the actual situation, and no further limitation is made herein.

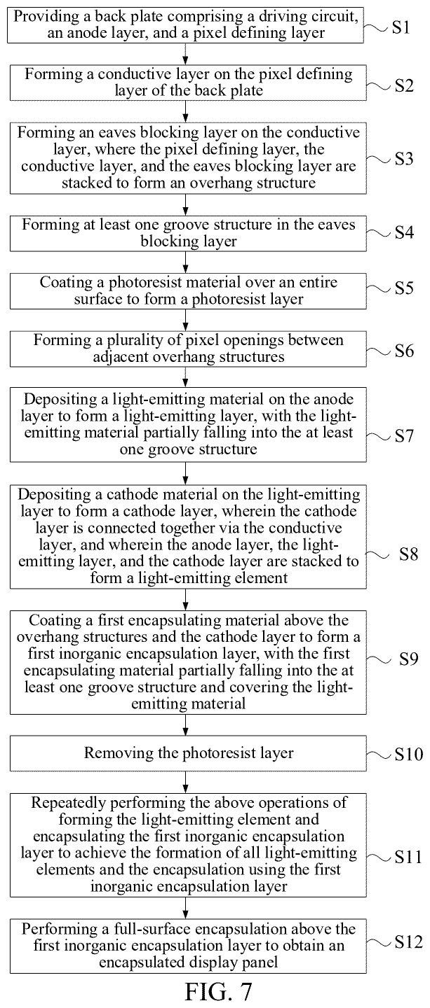

FIG. 7 is a flowchart illustrating a method for manufacturing a display panel provided in this application. As shown in FIG. 7, this application further discloses a method for manufacturing a display panel, used for manufacturing the display panel described above, including the following operations:
S1: providing a back plate, including a driving circuit, an anode layer, and a pixel defining layer;
S2: forming a conductive layer on the pixel defining layer;
S3: forming an eaves blocking layer on the conductive layer, where the pixel defining layer, the conductive layer, and the eaves blocking layer are stacked to form an overhang structure;
S4: forming a groove structure in the eaves blocking layer;
S5: coating the entire surface with a photoresist material to form a photoresist layer;
S6: forming pixel openings between adjacent overhang structures;
S7: depositing a light-emitting material above the anode layer to form a light-emitting layer, with some light-emitting material falling into the groove structure;
S8: depositing a cathode material above the light-emitting layer to form a cathode layer, which is connected through the conductive layer, where the anode layer, the light-emitting layer, and the cathode layer are stacked to form a light-emitting element;
S9: coating a first encapsulation material above the overhang structure and above the cathode layer to form a first inorganic encapsulation layer, with some first encapsulation material falling into the groove structure and covering the light-emitting material;
S10: removing the photoresist layer;
S11: repeating the operations of forming the light-emitting element and the first inorganic encapsulation layer to form all light-emitting elements and achieve the encapsulation of the first inorganic encapsulation layer;
S12: performing full-surface encapsulation above the first inorganic encapsulation layer to obtain the fully encapsulated display panel.

Performing full-surface encapsulation above the first inorganic encapsulation layer includes encapsulating using an organic encapsulation layer and encapsulating using a second inorganic encapsulation layer. When forming the groove structure, an etching process may be used while controlling different etching rates to form corresponding groove patterns. When forming the pixel openings, a photoresist material is first coated, followed by exposure and development to expose the pixel openings. In addition, a patterning process is carried out at the positions corresponding to the pixel openings to complete the fabrication of each pixel, details of which however will not be described herein.

It should be noted that the limitations of the various steps or operations involved in this solution are not to be interpreted to limit the order of the steps or operations, under the premise of not affecting the implementation of the specific solution. The steps or operations written earlier can be executed first, or later, or even at the same time with the steps or operations written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising:
a substrate;
a plurality of overhang structures, arranged on the substrate and spaced apart from each other, wherein adjacent overhang structures are arranged in an encircling manner to form a plurality of pixel openings;
a plurality of light-emitting elements, arranged in the plurality of pixel openings in one-to-one correspondence;
a first inorganic encapsulation layer, arranged on a side of the overhang structure facing away from the substrate; and
an organic encapsulation layer, arranged on a side of the first inorganic encapsulation layer facing away from the plurality of overhang structures;
light-emitting element;
wherein each of the plurality of overhang structures comprises a pixel defining layer, a conductive layer, and an eaves blocking layer that are stacked in sequence; wherein the eaves blocking layer comprises at least one groove structure in a side facing away from the conductive layer; wherein each of the at least one groove structure is sequentially filled with a light-emitting material and a first inorganic encapsulating material.

2. The display panel as recited in claim 1, wherein along an orientation in which each of the plurality of overhang structures is arranged, a width of a groove bottom of each groove structure is greater than a width of a groove opening of the groove structure.

3. The display panel as recited in claim 2, wherein a cross section of each groove structure is a trapezoidal structure, and wherein a base angle of the trapezoidal structure lies in the range of 60° to 80°.

4. The display panel as recited in claim 2, wherein let a groove depth of each groove structure be h, a width of the groove opening of the groove structure be b, and a thickness of the eaves blocking layer be H, then H=3 μm, ⅓H≤h≤½H, and 1 μm≤h≤1.5 μm; wherein b is set to lie in the following range: 1 μm≤b≤1.5 μm.

5. The display panel as recited in claim 4, wherein each groove structure runs through an entirety of the eaves blocking layer.

6. The display panel as recited in claim 1, wherein there is disposed a plurality of layers of each of the light-emitting material and the first inorganic encapsulating material, wherein the plurality of layers of the light-emitting material and the plurality of layers of the first inorganic encapsulating material are stacked in sequence.

7. The display panel as recited in claim 6, wherein the light-emitting material comprises a light-emitting material of a first color, a light-emitting material of a second color, and a light-emitting material of a third color;
wherein the first inorganic encapsulating material comprises a first layer of the first inorganic encapsulating material, a second layer of the first inorganic encapsulating material, and a third layer of the first inorganic encapsulating material;
wherein the light-emitting material of the first color, the first layer of the first inorganic encapsulating material, the light-emitting material of the second color, the second layer of the first inorganic encapsulating material, the light-emitting material of the third color, and the third layer of the first inorganic encapsulating material are sequentially formed in each groove structure.

8. The display panel as recited in claim 6, wherein the light-emitting material comprises a light-emitting material of a first color and a light-emitting material of a second color;
wherein the first inorganic encapsulating material comprises a first layer of the first inorganic encapsulating material and a second layer of the first inorganic encapsulating material;
wherein the light-emitting material of the first color, the first layer of the first inorganic encapsulating material, the light-emitting material of the second color, and the second layer of the first inorganic encapsulating material are sequentially formed in each groove structure.

9. The display panel as recited in claim 7, wherein the at least one groove structure comprises two groups of groove structures, each group comprising a first groove structure and a second groove structure; wherein a width of a groove opening of each of the first groove structure and the second groove structure is 1.5 μm, and wherein a spacing between the first groove structure and the second groove structure is greater than 1.5 μm.

10. The display panel as recited in claim 1, wherein the plurality of overhang structures comprise a first overhang structure and a second overhang structure; wherein the first overhang structure is correspondingly arranged between adjacent light-emitting elements, wherein the second overhang structure is arranged on a side facing away from the plurality of light-emitting elements;
wherein a size of the first overhang structure is equal to a size of the second overhang structure, wherein the first overhang structure comprises a first pixel defining layer, a first conductive layer, and a first eaves blocking layer that are stacked in sequence; wherein the second overhang structure comprises a second pixel defining layer, a second conductive layer, and a second eaves blocking layer that are stacked in sequence;
wherein a plurality of groove structures are arranged in each of the first eaves blocking layer and the second eaves blocking layer, wherein a number of the plurality of groove structures arranged in the first eaves blocking layer is less than a number of the plurality of groove structures arranged in the second eaves blocking layer.

11. The display panel as recited in claim 1, wherein the plurality of overhang structures comprise a first overhang structure and a second overhang structure, wherein the plurality of light-emitting elements comprise at least a plurality of first color light-emitting elements and a plurality of second color light-emitting elements;
wherein there is formed a first spacing region between two adjacent first color light-emitting elements, and a second spacing region between a first color light-emitting element and a second color light-emitting element that are adjacent to each other;
wherein the first overhang structure is correspondingly arranged in a respective first spacing region, and wherein the second overhang structure is correspondingly arranged in a respective second spacing region;
wherein a size of each first overhang structure is less than a size of each second overhang structure; wherein the first overhang structure comprises a first pixel defining layer, a first conductive layer, and a first eaves blocking layer that are stacked in sequence; wherein the second overhang structure comprises a second pixel defining layer, a second conductive layer, and a second eaves blocking layer stacked in sequence;
wherein a plurality of groove structures are arranged in each of the first eaves blocking layer and the second eaves blocking layer, wherein a number of the plurality of groove structures arranged in the first eaves blocking layer is less than a number of the plurality of groove structures arranged in the second eaves blocking layer.

12. The display panel as recited in claim 1, wherein along an orientation of a scan line of the display panel, the eaves blocking layer of each of the plurality of overhang structures comprises a plurality of first groove structures; wherein along an orientation of a data line of the display panel, the eaves blocking layer of each of the plurality of overhang structures comprises a plurality of second groove structures;
wherein a cross-sectional area of each first groove structure is less than a cross-sectional area of each second groove structure.

13. A method for manufacturing a display panel, comprising:
providing a back plate, the back plate comprising a driving circuit, an anode layer, and a pixel defining layer;
forming a conductive layer on the pixel defining layer of the back plate;
forming an eaves blocking layer on the conductive layer, wherein the pixel defining layer, the conductive layer, and the eaves blocking layer are stacked to form an overhang structure;
forming at least one groove structure in the eaves blocking layer;
coating a photoresist material over an entire surface to form a photoresist layer;
forming a plurality of pixel openings between adjacent overhang structures;
depositing a light-emitting material on the anode layer to form a light-emitting layer, with the light-emitting material partially falling into the at least one groove structure;
depositing a cathode material on the light-emitting layer to form a cathode layer, wherein the cathode layer is connected together via the conductive layer, and wherein the anode layer, the light-emitting layer, and the cathode layer are stacked to form a light-emitting element;
coating a first encapsulating material above the overhang structures and the cathode layer to form a first inorganic encapsulation layer, with the first encapsulating material partially falling into the at least one groove structure and covering the light-emitting material;
removing the photoresist layer;
repeatedly performing the above operations of forming the light-emitting element and encapsulating the first inorganic encapsulation layer to achieve the formation of all light-emitting elements and the encapsulation using the first inorganic encapsulation layer; and
performing a full-surface encapsulation above the first inorganic encapsulation layer to obtain an encapsulated display panel.

14. A display device, comprising a display panel, the display panel comprising:
a substrate;
a plurality of overhang structures, arranged on the substrate and spaced apart from each other, wherein adjacent overhang structures are arranged in an encircling manner to form a plurality of pixel openings;
a plurality of light-emitting elements, arranged in the plurality of pixel openings in one-to-one correspondence a first inorganic encapsulation layer, arranged on a side of the overhang structure facing away from the substrate; and
an organic encapsulation layer, arranged on a side of the first inorganic encapsulation layer facing away from the plurality of overhang structures; light-emitting element
wherein each of the plurality of overhang structures comprises a pixel defining layer, a conductive layer, and an eaves blocking layer that are stacked in sequence; wherein the eaves blocking layer comprises at least one groove structure in a side facing away from the conductive layer; wherein each of the at least one groove structure is sequentially filled with a light-emitting material and a first inorganic encapsulating material.

15. The display device as recited in claim 14, along an orientation in which each of the plurality of overhang structures is arranged, a width of a groove bottom of each groove structure is greater than a width of a groove opening of the groove structure.

16. The display device as recited in claim 15, wherein a cross section of each groove structure is a trapezoidal structure, and wherein a base angle of the trapezoidal structure lies in the range of 60° to 80°.

17. The display device as recited in claim 15, wherein let a groove depth of each groove structure be h, a width of the groove opening of the groove structure be b, and a thickness of the eaves blocking layer be H, then H=3 μm, ⅓H≤h≤½H, and 1 μm≤h≤1.5 μm; wherein b is set to lie in the following range: 1 μm≤b≤1.5 μm.

18. The display device as recited in claim 17, wherein each groove structure runs through an entirety of the eaves blocking layer.

19. The display device as recited in claim 14, wherein there is disposed a plurality of layers of each of the light-emitting material and the first inorganic encapsulating material, wherein the plurality of layers of the light-emitting material and the plurality of layers of the first inorganic encapsulating material are stacked in sequence.

20. The display device as recited in claim 19, wherein the light-emitting material comprises a light-emitting material of a first color, a light-emitting material of a second color, and a light-emitting material of a third color;
wherein the first inorganic encapsulating material comprises a first layer of the first inorganic encapsulating material, a second layer of the first inorganic encapsulating material, and a third layer of the first inorganic encapsulating material;
wherein the light-emitting material of the first color, the first layer of the first inorganic encapsulating material, the light-emitting material of the second color, the second layer of the first inorganic encapsulating material, the light-emitting material of the third color, and the third layer of the first inorganic encapsulating material are sequentially formed in each groove structure.
